(19) United States
(12) Patent Application Publication
(10) Pub. No.: US 2015/0228822 A1
(43) Pub. Date: Aug. 13, 2015

(54) SOLAR CELL

(71) Applicant: Panasonic Intellectual Property Management Co., Ltd., Osaka (JP)

(72) Inventors: Daisuke FUJISHIMA, Osaka (JP); Isao HASEGAWA, Hyogo (JP); Daisuke IDE, Hyogo (JP)

(21) Appl. No.: 14/695,625

(22) Filed: Apr. 24, 2015

Related U.S. Application Data
(63) Continuation of application No. PCT/JP2013/006408, filed on Oct. 29, 2013.

(30) Foreign Application Priority Data
Oct. 31, 2012 (JP) 2012-240143

(51) Int. Cl. H01L 31/0224; H01L 31/0376

(52) U.S. Cl. CPC H01L 31/022466; H01L 31/03762

(57) ABSTRACT

A solar cell includes a photoelectric conversion element that is formed by planate disposing, on an n-type single crystal Si substrate, an n layer that is an n-type amorphous semiconductor layer, and a player that is a p-type amorphous semiconductor layer, a transparent conductive film layer that is formed on the n layer and the p layer, and an electrode layer formed on the transparent conductive film layer. The density of the transparent conductive film layer, the density being on the n layer side and the p layer side, is lower than that on the electrode layer side.

### CROSS REFERENCE TO RELATED APPLICATIONS

This application is a continuation under 35 U.S.C. §120 of PCT/JP2013/006408, filed Oct. 29, 2013, which is incorporated herein reference and which claimed priority under 35 U.S.C. §119 to Japanese Application No. 2012-240143, filed Oct. 31, 2012, the entire content of which is also incorporated herein by reference, and 35 U.S.C. §119 priority is also claimed hereto.

### TECHNICAL FIELD

The present invention relates to a back contact solar cell.

### RELATED ART

A known photovoltaic device has a p-n junction formed from an amorphous semiconductor, wherein a sandwiched thin film of intrinsic amorphous semiconductor exists in the p-n junction (Patent Document 1).

Patent Document 2 discloses a double-junction solar cell having a first principal surface formed from an n-type semiconductor layer and a second principal surface formed from a p-type semiconductor layer. A hydrogen content of a first transparent conductive film formed on the first principal surface is lower than a hydrogen content of a second transparent conductive film formed on the second principal surface. It is said that this makes it possible to reduce the influence of hydrogen radicals on an upper surface of the n-type semiconductor layer making up the first principal surface. Additionally disclosed is that a rate of hydrogen content of the other side of the first transparent conductive film is made higher than a rate of hydrogen content of the n-type-semiconductor-layer-side of the first transparent conductive film.

### PRIOR ART DOCUMENTS

### Patent Document

Patent Document 1: Japanese Unexamined Patent Application No. Hei-4-199750

Patent Document 2: PCT International Publication No. WO 2009/116580

### SUMMARY OF THE INVENTION

### Problem that the Invention is to Solve

In the back contact solar cell, the transparent conductive films need to be provided with an optimal structure from the viewpoint of adhesion.

### Means for Solving the Problem

A solar cell comprising:
a photoelectric conversion element including an amorphous conductor layer of a first conductivity type and an amorphous semiconductor layer of a second conductivity type that are laid on one surface of a semiconductor substrate of the first conductivity type;

a transparent conductive film made up of a first region arranged on the amorphous semiconductor layer of the first conductivity type and a second region arranged on the amorphous semiconductor layer of the second conductivity type;

an electrode layer made up of a first electrode arranged on the first region of the transparent conductive film and a second electrode arranged on the second region, wherein

a density of a part of the transparent conductive film on the amorphous semiconductor layer of the first conductivity type side and the density on the amorphous semiconductor layer of the second conductivity type side is lower than a density of a part of the transparent conductive film on the electrode layer side.

### Advantage of the Invention

The configuration enables optimization of adhesion of the part of the transparent conductive film facing the amorphous semiconductor layer and adhesion of the transparent conductive film facing the electrode layer.

### BRIEF DESCRIPTION OF THE DRAWINGS

FIG. 1 is a cross sectional view of a solar cell of an embodiment of the present invention;

FIG. 2 is a graph relating to a transparent conductive film of the embodiment of the present invention showing a relationship between density of the transparent conductive film and contact resistance of a part of the transparent conductive film facing an amorphous semiconductor layer; and

FIG. 3 is a graph relating to the transparent conductive film of the embodiment of the present invention showing a relationship between the density of the transparent conductive film and increments in contact resistance of a part of the transparent conductive film facing an electrode layer, which is acquired through a reliability test.

### MODES FOR IMPLEMENTING THE INVENTION

An embodiment of the present invention is hereunder descried in detail by reference to the drawings. Thicknesses, and others, referred to hereinbelow are illustrative and can be modified appropriately according to specifications of a solar cell. Similar reference numerals are hereafter given to similar elements throughout the drawings, and their repeated explanations are omitted.

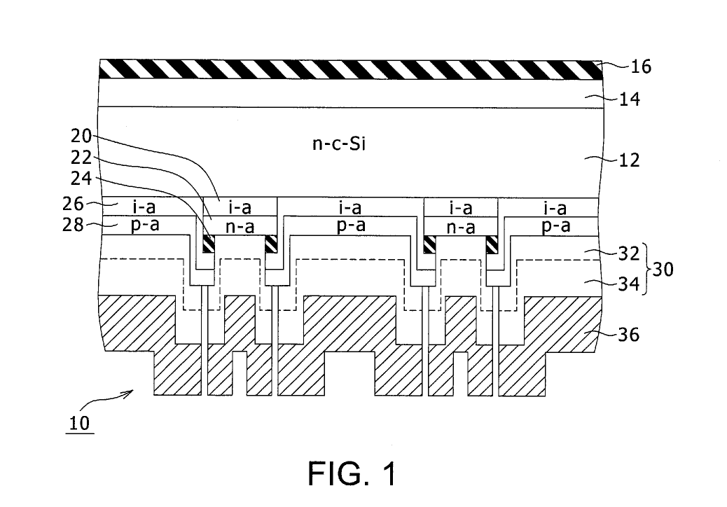

FIG. 1 is a cross sectional view showing a structure of a back contact solar cell 10. In a back contact solar cell 10, a p-n junction that performs photoelectric conversion is created on aback side opposite to a light-receiving surface of the solar cell, and electrodes are made solely on the back side. Thus, since no electrodes are placed on the light-receiving surface at all, a wide light-receiving area is guaranteed, and the efficiency of photoelectric conversion per unit area is improved. In FIG. 1, a top side of a drawing sheet is a light-receiving side, and a bottom side corresponds to a backside. In addition, unless otherwise specified, the back contact solar cell 10 is hereinbelow referred to simply as a solar cell 10.

In FIG. 1, a substrate 12 is made up of a crystalline semiconductor material. The substrate 12 can be embodied as an n-type or p-type conductive crystalline semiconductor substrate. A mono-crystalline silicon substrate, a polycrystalline silicon substrate, a gallium arsenic (GaAs) substrate, an indium phosphide (InP) substrate, etc., can be used for the substrate 12. The substrate 12 absorbs incident light, inducing electron-hole carrier pairs through photoelectric conversion. An example using an n-type single crystal silicon will be hereinbelow described. The substrate 12 is labeled as n-c-Si in FIG. 1.

A passivation layer 14 is laid on a light-receiving surface of the substrate 12 where photoelectric conversion takes place, and is a layer that protects a surface of the substrate 12 and that has a multilayer structure consisting of an i-type amorphous semiconductor layer and an n-type amorphous semiconductor layer. The i-type amorphous semiconductor layer is hereunder called an “i” layer, and the n-type amorphous semiconductor layer is hereinbelow called an “n” layer. Likewise, a p-type amorphous semiconductor layer is called a “p” layer.

An antireflection layer 16 is an insulation film layer laid on the passivation layer 14 and having a function of inhibiting reflection of the light-receiving surface, and an SiNx layer is used.

An i-layer 20 for use as an n-type region is formed on a backside of the cleaned substrate 12. The substrate 12 is cleaned with an aqueous solution of hydrofluoric acid (HF) or a cleaning solution of RCA. After cleaning of the substrate 12, a texture structure can also be made on a front or back side of the substrate with an alkaline etchant, such as an aqueous solution of potassium hydroxide (KOH).

The i-layer 20 can be embodied as, for instance, an amorphous semiconductor layer containing hydrogen. The i-layer 20 is labeled as “i-a” in FIG. 1. The i-layer 20 can be made by plasma CVD, and other methods. For instance, a silicon-containing gas, such as silane (SiH₄), and hydrogen serving as a diluent gas, are supplied, and RF power is applied to parallel-plate-type electrodes, whereby the gases transform into a plasma state. The gases in their plasma states are fed to a film formation surface of the heated substrate, so that the i-layer is thereby made. An example thickness of the i-layer 20 is about 1 to 25 nm, and a preferable thickness should be about 3 to 10 nm.

An n-layer 22 is formed on the i-layer 20. The n-layer 22 includes donors that are n-type conductive elements. The n-layer 22 is labeled as n-a in FIG. 1. The n-layer 22 can also be made by plasma CVD, etc. For instance, a gas containing an n-type element such as phosphine (PH₃) is added to the silicon-containing gas, like silane (SiH₄). The mixture is fed, while being diluted by hydrogen, and RF power is applied to parallel-plate-type electrodes, whereby the gases transform into a plasma state. The gases in their plasma states are fed to the film formation surface of the heated substrate, so that the n-layer 22 is thereby made. An example thickness of the n-layer 22 is about 5 to 20 nm, and a preferable thickness should be about 10 to 15 nm.

An “n” region is formed from the i-layer 20 and n-layer 22. Being created on a backside of the substrate 12, the i-layer 20 and n-layer 22 are concurrently created on the light-receiving surface too. These layers can be taken as a light-receiving-surface-side passivation layer 14.

A SiNx layer 24 is a silicon nitride film layer used for isolating an n-type region from a p-type region. A typical silicon nitride is Si₃N₄. A composition of Si₃N₄ does not always appear depending on conditions for film formation, and a composition of SiNx generally appears. The SiNx layer 24 can also be created by plasma CVD, and the like. For instance, the SiNx layer 24 is created by feeding a nitrogen gas along with a silicon-containing gas, such as silane (SiH4), applying RF power to the parallel-plate-type electrodes to transform the gases into a plasma state, and feeding the gases in their plasma state to the film formation surface of the heated substrate. An example thickness of the SiNx layer 24 is about 10 to 500 nm and should preferably be about 50 to 100 nm.

Being created on the backside of the substrate 12, the SiNx layer 24 is concurrently created on the light-receiving surface too, and this layer can be taken as a light-receiving-surface-side antireflection layer 16.

The i-layer 20 and the n-layer 22 located outside the n-type region are eliminated by using the SiNx layer 24 as a mask, thereby exposing the substrate 12. Thus, the i-layer 26 for use as a p-type region is created on the exposed substrate 12. Like the i-layer 20 for use as an n-type region, the i-layer 26 for use as a p-type region can also be created by means of plasma CVD, or the like. The thickness of the i-layer 26 is about 1 to 25 nm as in the case with the i-layer 20 and should preferably be about 3 to 10 nm.

A p-layer 28 is created on the i-layer 26. In the p-layer 28, acceptors that are elements of p-type conductivity are included in a hydrogen-containing amorphous semiconductor layer. In FIG. 1, the p-layer 28 is designated as p-a. The p-layer can be created by plasma CVD, and the like. An example thickness of the p-layer 28 is about 5 to 20 nm and should preferably be about 10 to 15 nm. A p-type region is created from the i-layer 26 and the p-layer 28.

A transparent conductive film layer 30 is created on the p-layer 28 and the n-layer 22. Since the n-layer 22 is covered with the SiNx layer 24 during creation of the p-type region, apertures are created in the SiNx layer 24 on the n-layer 22 prior to creation of the TCO 30.

For instance, the transparent conductive film layer 30 contains at least one of metal oxides having a polycrystalline structure, such as indium oxide (In₂O₃), zinc oxide (ZnO), and tin oxide (TiO₂). The metal oxide is doped with an element, such as tin (Sn), zinc (Zn), tungsten (W), antimony (Sb), titanium (Ti), cerium (Sb), and gallium (Ga). The transparent conductive film layer 30 can be created by a thin-film creation technique, such as sputtering, deposition, plasma CVD, and others. An example thickness of the transparent conductive film layer 30 is about 50 to 150 nm.

The transparent conductive film layer 30 is made up of a two-layer structure. Specifically, the structure includes an amorphous-semiconductor-layer-side first layer 32 contacting the p-layer 28 and the n-layer 22 and an electrode-layer-side second layer 34 which is on the other side of the first layer 32 and which contacts an electrode layer 36 to be described later. In order to optimize contact resistance of an amorphous-semiconductor-layer-side of the first layer 32 and contact resistance of an electrode-layer-side of the second layer 34, the first conductor layer 32 and the second conductor layer 34 are formed at different densities. The first layer 32 and the second layer 34 having different densities can be created by changing, for instance, conditions for film formation in sputtering, deposition, and plasma CVD, for the first layer 32 and the second layer 34. Detailed settings about the density of the first layer 32 and the density of the second layer 34 will be described later.

The second layer 34 is set so as to become thicker than the first layer 32. By way of example, the film thickness of the first layer 32 can be set to about 15 to 35 nm, and the film thickness of the second layer 34 can be set to about 35 to 115 nm.

The electrode layer 36 is a Cu plating layer deposited on the transparent conductive film layer 30. The electrode layer 36 is created while being separated into an n-type electrode and a p-type electrode. Alternatively, the electrode layer 36 can also be created from a base electrode layer and the Cu plating layer. In this case, the base electrode layer is laid on the transparent conductive film layer 30, and a layered material consisting of the transparent conductive film layer 30 and the base electrode layer is separated into a layer for use as an n-type electrode and a layer for use as a p-type electrode. A Cu plating layer is stacked on the thus-separated base electrode layer by means of electrolytic plating. The base electrode layer is a Cu layer and is created by sputtering, deposition, and other methods. An example thickness of the base electrode layer ranges 100 nm to 1 μm. Etching is used for separating the layered material into the layer for an n-type electrode and the layer for a p-type electrode. An example thickness of the Cu plating layer ranges from about 10 μm to 40 μm. Incidentally, a Sn plating layer, a Ni plating layer, or the like, can also be created on the electrode layer 36. An example thickness of the Sn plating layer, or the like, ranges from about 1 to 2 μm.

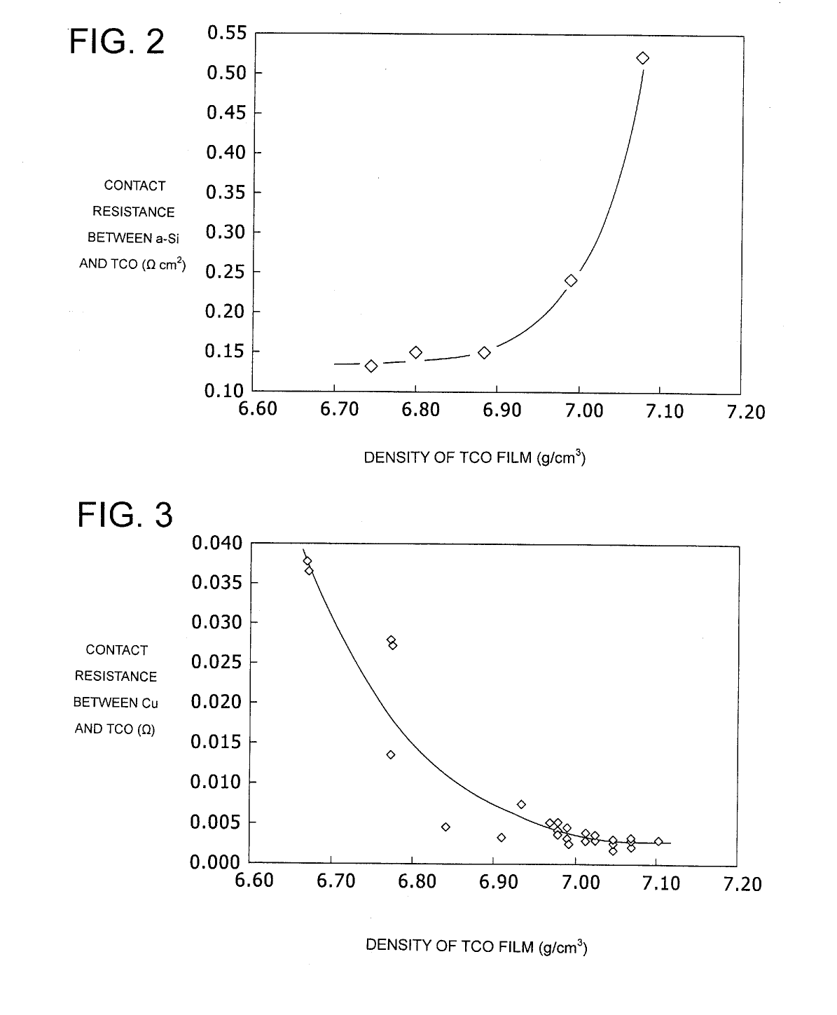

Explanations will now be given regarding settings on densities of the first layer 32 and the second layer 34 in the two-layer structure of the transparent conductive film layer 30 by reference to FIGS. 2 and 3.

FIG. 2 is a graph showing a result of a test conducted for setting the density of the first layer 32. The horizontal axis of the graph indicates a film density of the transparent conductive film (Transparent Conductive Film: TCO), and the vertical axis of the same indicates contact resistance existing between the amorphous semiconductor layer (a-Si) and the transparent conductive film layer (TCO). The contact resistance is used as an index for evaluating adhesion between the amorphous semiconductor layer and the transparent conductive film layer.

Contact resistance can be measured according to a TLM (Transmission Line Model). TLM is a technique of using a model in which contact resistance is connected to each end of a resistor by utilization of a phenomenon in which a resistance value becomes greater with an increase in a resistor's length, whereas contact resistance remains constant and unchanged. For instance, a plurality of electrodes are formed on an amorphous semiconductor layer from a transparent conductive film, and a distance D between electrodes is changed. Thereupon, the resistance of the amorphous semiconductor layer changes in proportion to D. A few items of data are sampled by changing D. A resistance value of an intercept of D=0 is determined, and contact resistance can be calculated from the resistance value.

The result illustrated in FIG. 2 shows that adhesion between the amorphous semiconductor layer and the transparent conductive film layer is superior and becomes stable when the density of the transparent electrode film layer is less than 6.90 g/cm³. It is also seen that adhesion becomes more superior and stable when the density is less than 6.80 g/cm³. From the above, the film density of the first layer 32 situated on the amorphous semiconductor layer side of the transparent conductive film layer 30 is set to less than 6.90 g/cm³. More preferably, it is better to set the density to less than 6.80 g/cm³. In this regard, according to the data shown in FIG. 2 a lower limit of the film density of the first layer 32 can be set to about 6.70 g/cm³.

FIG. 3 is a graph showing a result of a test conducted for setting the density of the second layer 34. The horizontal axis of the graph indicates a film density of the transparent electrode (TCO), and the vertical axis of the same indicates increments that occur in contact resistance between the Cu layer and the transparent conductive film layer (TCO), which serve as the electrode layer 36, before and after a reliability test. The increments that arise in contact resistance before and after the reliability test are used as an index for evaluating adhesion between the electrode layer and the transparent conductive film layer.

The results of FIG. 3 show that adhesion between the electrode layer and the transparent conductive film layer becomes superior and stable when the density of the transparent electrode film layer is from 6.90 g/cm³ to 7.15 g/cm³. It is seen that adhesion becomes more stable and superior when the density is from 7.00 g/cm³ to 7.15 g/cm³. In addition, the adhesion becomes much more superior and stable when the density is from 7.05 g/cm³ to 7.15 g/cm³.

Therefore, film density of the second layer 34 on the electrode layer side of the transparent electrode film layer 30 is set to a range from 6.90 g/cm³ to 7.15 g/cm³; preferably from 7.00 g/cm³ to 7.15 g/cm³; and more preferably from 7.05 g/cm³ to 7.15 g/cm³.

As described above, adhesion of the amorphous-semiconductor-layer-side of the transparent conductive film and adhesion of the electrode-layer-side of the transparent conductive film can be optimized by setting the density of the amorphous-semiconductor-layer-side of the transparent conductive film and the density of the electrode-layer-side of the transparent conductive film to respective appropriate values.

### INDUSTRIAL APPLICABILITY

The present invention can be utilized for aback junction solar cell.

### DESCRIPTIONS OF THE REFERENCE NUMERALS

10 SOLAR CELL, 12 SUBSTRATE, 14 PASSIVATION LAYER, 16 ANTIREFLECTION LAYER 20, 26 “i” LAYER, 22 “n” LAYER, 24 SiNx LAYER, 28 “p” LAYER, 30 TRANSPARENT CONDUCTIVE FILM. LAYER, 32 FIRST LAYER, 34 SECOND LAYER, 36 ELECTRODE LAYER

1. A solar cell comprising:
a photoelectric conversion element including an amorphous semiconductor layer of a first conductivity type and an amorphous semiconductor layer of a second conductivity type that are laid on one surface of a semiconductor substrate of the first conductivity type;
a transparent conductive film made up of a first region arranged on the amorphous semiconductor layer of the first conductivity type and a second region arranged on the amorphous semiconductor layer of the second conductivity type; and
an electrode layer made up of a first electrode arranged on the first region of the transparent conductive film and a second electrode arranged on the second region, wherein
a density of a part of the transparent conductive film on the amorphous semiconductor layer of the first conductivity type side and the density on the amorphous semiconductor layer of the second conductivity type side is lower than a density of a part of the transparent conductive film on the electrode layer side.

2. The solar cell according to claim 1, wherein the transparent conductive film includes a first layer formed on the amorphous semiconductor layer of the first conductivity type and the amorphous semiconductor layer of the second conductivity type, and a second layer formed on the first layer.

3. The solar cell according to claim 2, wherein the second layer of the transparent conductive film is thicker than the first layer of the transparent conductive film.

4. The solar cell according to claim 1, wherein the density of the part of the transparent conductive film on the first amorphous semiconductor layer of the first conductivity type side and the second amorphous semiconductor layer of the second conductivity type is from 6.70 g/cm³ and less than 6.90 g/cm³, and the density of the part of the transparent conductive film on the electrode layer side is from 7.00 g/cm³ to 7.15 g/cm³.

5. The solar cell according to claim 4, wherein the density of the part of the transparent conductive film on the electrode layer side is from 7.05 g/cm³ to 7.15 g/cm³.
